(19) United States
(12) Patent Application Publication
(10) Pub. No.: US 2005/0064339 A1
(43) Pub. Date: Mar. 24, 2005

(54) Planographic printing plate material and printing process

(75) Inventor: Masaki Miyoshi, Tokyo (JP)

Correspondence Address: Finnegan, Henderson, Farabow,;Garrett & Dunner, L.L.P., 1300 I Street, N.W., Washington, DC, 20005-3315, US

(73) Assignee: KONICA MINOLTA MEDICAL & GRAPHIC, INC.

(21) Appl. No.: 10/943,935

(22) Filed: Sep. 20, 2004

(30) Foreign Application Priority Data
Sep. 24, 2003 (JP) JP2003-331205

(51) Int. Cl. G03F 7/00

(52) U.S. Cl. 430/300

(57) ABSTRACT

Disclosed are a planographic printing plate material and a printing process, the planographic printing plate material comprising a plastic film sheet support and provided thereon, a hydrophilic layer and an image formation layer in that order, wherein the image formation layer contains extender pigment.

### FIELD OF THE INVENTION

The present invention relates to a planographic printing plate material, and particularly to a planographic printing plate material capable of being developed on a press, providing high contrast between exposed and unexposed portions, and a printing process employing the same.

### BACKGROUND OF THE INVENTION

An inexpensive planographic printing plate material for CTP (Computer to Plate) system, which can be easily handled and has a printing ability comparable with that of PS plates, is required accompanied with the digitization of printing data. Recently, a so-called processless plate material requiring no development due to a specific developer is strongly desired, which can be applied to a printing press (DI printing press) installed with a direct imaging (DI) system.

A processless plate material is considered which employs a grained aluminum plate like that of PS plates. However, in view of freedom of layer constitution and cost reduction, various processless plate materials, which employ a coated hydrophilic layer, have been proposed.

At present, such-a processless plate material is applied only to a DI printing press. There are no proposals of a processless plate material having sufficient printing properties as a versatile printing plate material.

As one of insufficiencies of the versatile printing plate material, there is lowness of contrast between exposed and unexposed portions (visualization due to exposure).

As the processless plate, a so-called thermal type printing plate material has been mainly used, on which an image is recorded employing infrared laser exposure. The thermal type printing plate material can be divided into two types. One is an ablation type printing plate material comprising a support and provided thereon, two layers being different from each other in affinity to a dampening solution or printing ink used during printing, in which the layer on the outer side is ablated by laser exposure to remove. In the printing plate material of this type, visualization due to exposure can be provided by the two layers above having different color tone, and there is a printing plate material disclosed in for example, Japanese Patent Publication No. 2002-514984. However, in order to employ a printing plate material of this type, it is necessary that a means for removing completely scattered matter produced by ablation of the surface layer be installed in an exposure device used, which results in problem of greatly increasing cost of the device. Further, since exposure energy necessary to expose is relatively high, it is necessary to lower the scanning speed of exposure beam during exposure (for example, to decrease rate of rotation of an exposure drum), which may lower image formation speed.

The other is an on-press development type printing plate material comprising a support and provided thereon, two layers being different from each other in affinity to a dampening solution or printing ink used during printing, in which adhesion force between the two layers is varied by laser exposure and the layer at portions where the adhesion force has been reduced by laser exposure is removed on a press. Removal of the layer where the adhesion force has been reduced can be carried out according to various methods. There are, for example, a method in which that layer is brought into contact with a dampening roller to be dissolved or swelled in dampening solution, a method in which that layer is brought into contact with an ink roller to be removed employing tackiness of the ink, and a method in which that layer is brought into contact with a blanket cylinder to be removed.

In the on-press development type printing plate material, it is desired that the surface layer to be removed on a press be colorless, since it is necessary to minimize staining of the dampening solution or printing ink. The colored layer makes it difficult to provide good visualization property.

A printing plate material providing good visualization property is disclosed which comprises a heat-sensitive layer containing an infrared absorbing dye whose optical density changes on exposure (see for example, Japanese Patent O.P.I. Publication No. 11-240270). Generally, such a dye, though it fades away on infrared light exposure, does not completely lose its color. This means that even the surface layer at exposed portions, which has been removed on a press, contaminates the dampening solution or printing ink. In order to improve a visualization property, it is necessary to increase contrast between a layer at exposed portions and a layer at unexposed portions, i.e. to increase an optical density at unexposed portions. Accordingly, improvement of visualization property and prevention of contamination of a press are incompatible, in the printing plate material of the type removing a layer at unexposed portions.

As a method for increase contrast between a layer at exposed portions and a layer at unexposed portions in a layer containing no coloring material of a printing plate material of the on-press development type, there has been proposed a method of heating a printing plate material comprising a recording layer containing heat melting particles and a porous void-containing layer to heat-melt the heat melting particles and to fill the void-containing layer with the heat-melting particles, whereby an image with contrast of transparency and opacity is obtained (see for example, Japanese Patent O.P.I. Publication No. 2001-322226). However, visualization according to this method is practically unsatisfactory.

It is well known that the difference in refractive index between a dispersion medium and extender pigment greatly varies transparency and whiteness.

According to the invention, incorporation of extender pigment can provide a processless plate with improved visualization property and plate inspectability.

### SUMMARY OF THE INVENTION

An object of the invention is to provide a planographic printing plate material providing high contrast between the exposed and unexposed portions, which is capable of providing a printing plate by means of simple water development or of providing a printing plate on a printing press without specific development, and a printing process employing the planographic printing plate material.

### DETAILED DESCRIPTION OF THE INVENTION

The above object of the invention can be attained by the following constitutions:

1. A planographic printing plate material comprising a plastic film sheet support and provided thereon, a hydrophilic layer and an image formation layer in that order, wherein the image formation layer contains extender pigment.

2. The planographic printing plate material of item 1 above, wherein the extender pigment is in the form of particles and the particles have an average particle diameter of from 0.05 μm to less than 2 μm.

3. The planographic printing plate material of item 1 above, wherein the extender pigment content of the image formation layer is from 1% by weight to less than 25% by weight.

4. The planographic printing plate material of item 1 above, wherein the extender pigment has a refractive index of from 1.35 to less than 1.7.

5. The planographic printing plate material of item 1 above, wherein the extender pigment is one selected from the group consisting of calcium carbonate, barium sulfate and titanium oxide.

6. The planographic printing plate material of item 1 above, wherein the image formation layer further contains heat-melting particles or heat-fusible particles.

7. The planographic printing plate material of item 1 above, wherein the hydrophilic layer consists of two hydrophilic layers, which are formed according to a coating method.

8. The planographic printing plate material of item 1 above, wherein the hydrophilic layer contains metal oxide particles with an average particle diameter of from 3 to 100 nm.

9. The planographic printing plate material of item 8 above, wherein the metal oxide particles are colloidal silica.

10. The planographic printing plate material of item 8 above, wherein the hydrophilic layer further contains a light-to-heat conversion material.

11. The planographic printing plate material of item 1 above, wherein the plastic film sheet support is that of polyethylene terephthalate or polyethylene naphthalate.

12. A printing process comprising the step of writing an image based on image information on the planographic printing plate material of any one of claims 1 through 11 above, employing infrared laser, and carrying out printing, employing the resulting planographic printing plate material without being subjected to special development.

In the invention, incorporation of extender pigment to the image formation layer improves the visualization. Examples of useful extender pigment include calcium carbonate, barium sulfate, titanium oxide, calcium carbonate, aluminum oxide, and zinc oxide. Preferred extender pigment is calcium carbonate or barium sulfate. However, the extender pigment in the invention is not limited thereto as long as it has a refractive index of from 1.35 to less than 1.7. Refractive index falling outside the above range does not provide transparency at exposed portions, resulting in insufficient contrast.

The extender pigment in the invention has an average particle diameter of preferably from 0.05 μm to less than 2 μm. An average particle diameter less than 0.05 μm does not provide sufficient whiteness at non-exposed portions, while an average particle diameter of not less than 2 μm does not provide transparency at exposed portions. The average particle diameter of extender pigment can be measured employing a particle diameter measuring device available on the market employing a light scattering method, an electrophoresis method or a laser Doppler method.

The extender pigment in the invention may be subjected to organic polymer treatment, acid treatment or alkali treatment, after formation of particles.

The content of the extender pigment in the image formation layer is preferably from 1% by weight to less than 25% by weight, and more preferably from 1% by weight to less than 10% by weight. The content of the extender pigment less than 1% by weight does not provide sufficient whiteness at non-exposed portions, while the content of the extender pigment not less than 25% by weight does not provide transparency at exposed portions.

Materials for the plastic film sheet support in the invention (hereinafter also referred to as the support in the invention) include polyethylene terephthalate, polyethylene naphthalate, polyimide, polyamide, polycarbonate, polysulfone, polyphenylene oxide, and cellulose ester.

The support in the invention has a coefficient of elasticity at 120° C. (E120) of preferably from 100 to 600 kg/mm², and more preferably from 120 to 500 kg/mm², in view of a handling property. Examples of such a support include a sheet of polyethylene naphthalate (E120=410 kg/mm²), polyethylene terephthalate (E120=150 kg/mm²), polybutylene naphthalate (E120=160 kg/mm²), polycarbonate (E120=170 kg/mm²), syndiotactic polystyrene (E120=220 kg/mm²), polyetherimide (E120=190 kg/mm²), polyarylate (E120=170 kg/mm²), polysulfone (E120=180 kg/mm²), and polyethersulfone (E120=170 kg/mm²) . These plastics may be used singly or as a mixture of two or more thereof. Two or more of these sheets may be laminated. Especially preferred support is a polyethylene naphthalate sheet or a polyethylene terephthalate sheet.

The coefficient of elasticity herein referred to is a slope of the straight line portion in the stress-strain diagram showing the relationship between strain and stress, which is obtained employing a tension test meter according to JIS C2318. This slope is called Young's modulus, which is defined in the invention as coefficient of elasticity.

It is preferred that the support in the invention has an average thickness of from 50 to 500 μm, and a thickness distribution of not more than 10%, in that a handling property is improved when the planographic printing plate material is mounted on a press.

The average thickness of the support in the invention is preferably from 50 to 500 μm, more preferably from 100 to 400 μm, and still more preferably from 120 to 300 μm.

The thickness dispersion of the support in the invention is preferably not more than 10%, more preferably not more than 8%, and still more preferably not more than 6%. The thickness dispersion herein referred to means a value (%) obtained by dividing the difference between the maximum thickness and the minimum thickness by the average thickness and then multiplying the difference by 100.

The thickness dispersion of the support is determined according to the following: lines are formed at an interval of 10 cm in both the transverse and longitudinal directions on a 60 cm square polyester film sheet to form 36 small squares. The thickness of the 36 small squares is measured, and the average thickness, maximum thickness and minimum thickness are obtained therefrom.

In order to obtain an average thickness or thickness dispersion of the support in the invention falling within the range described above, there is a method in which support forming conditions are optimized or the support prepared is treated with a smoothing roller while post heating, however, it is preferred that the support is prepared according to the following procedures.

The support in the invention is prepared by a method comprising the steps of melting a thermoplastic resin at a temperature of from the melting point (Tm) to Tm+50° C., filtering the melted resin through a filter, extruding the filtrate from a T-die, and casting it on a casting drum at a glass transition point (Tg) −50° C. to Tg to form an unstretched sheet. As a method to obtain the support with the thickness variation falling within the above-described range, a static electricity application method is preferably used.

The unstretched sheet is stretched at from Tg to Tg+50° C. by a stretching magnification of from 2 to 4. As another method to obtain the support with the thickness variation falling within the above-described range, a multi-stretching method is preferably used, in which temperature at a later stretching step is higher than that at a preceding stretching step by preferably 1 to 30° C., and more preferably 2 to 15° C.

The stretching magnification at the preceding stretching step is preferably 0.25 to 0.75 times, and more preferably 0.3 to 0.5 times the stretching magnification at the later stretching step. Thereafter, it is preferred that the stretched sheet is maintained at Tg−30° C. to Tg for 5 to 60 seconds, preferably 10 to 40 seconds, and stretched in the lateral direction at Tg to Tg+50° C. by a stretching magnification of 2.5 to 5.

The resulting sheet, while held through a chuck at (Tm−50° C.) to (Tm−5° C.), is heat fixed for 5 to 120 seconds, where the interval of the chucks in the lateral direction is preferably reduced by more than 0 to 10% (heat relaxation). The heat fixed sheet is cooled, subjected to knurling treatment to give a knurl of 10 to 100 μm at the sheet edge, and wounded around a spool. Thus, a multi-axially stretched film sheet is preferably obtained.

In order to increase adhesion between the support and a coating layer, it is preferred that the surface of the support is subjected to adhesion increasing treatment or is coated with a subbing layer. Examples of the adhesion increasing treatment include corona discharge treatment, flame treatment, plasma treatment and UV light irradiation treatment.

The subbing layer is preferably a layer containing gelatin or latex. The electrically conductive layer, for example, an electrically conductive polymer-containing layer disclosed in items [0031] through [0073] of Japanese Patent O.P.I. Publication No. 7-20596 or a metal oxide-containing layer disclosed in items [0074] through [0081] of Japanese Patent O.P.I. Publication No. 7-20596 is preferably provided on the support. The electrically conductive layer may be provided on any surface side of the support, but is provided preferably on the surface of the support opposite the image formation layer. The electrically conductive layer improves electrification property, reduces dust adhesion, and greatly lowers printing failure such as white spot occurrence during printing.

The support in the invention is preferably a plastic sheet, but may be a composite support in which a plate of a metal (for example, iron, stainless steel or aluminum) or a polyethylene-laminated paper sheet is laminated onto the plastic sheet. The composite support may be one in which the lamination is carried out before any layer is coated on the support, one in which the lamination is carried out after any layer has been coated on the support, or one in which the lamination is carried out immediately before mounted on a printing press.

Particles having a size of from 0.01 to 10 μm are preferably incorporated in an amount of from 1 to 1000 ppm into the support, in improving handling property.

Herein, the particles may be organic or inorganic material. Examples of the inorganic material include silica described in Swiss Patent 330158, glass powder described in French Patent 296995, and carbonate salts of alkaline earth metals, cadmium or zinc described in British Patent 1173181. Examples of the organic material include starch described in U.S. Pat. No. 2,322,037, starch derivatives described such as in Belgian Patent 625451 and British Patent 981198, polyvinyl alcohol described in JP-B 44-3643, polystyrene or polymethacrylate described in Swiss Patent 330158, polyacrylonitrile described in U.S. Pat. No. 3,079,257 and polycarbonate described in U.S. Pat. No. 3,022,169. The shape of the particles may be in a regular form or irregular form.

The water content of the support is preferably not more than 0.5% by weight, more preferably from 0.01 to 0.5% by weight, and most preferably not more than 0.3% by weight.

As a method of obtaining a support having a water content of not more than 0.5% by weight, there are (1) a method in which the support is heat treated at not less than 100° C. immediately before an image formation layer or another layer is coated on the support; (2) a method in which an image formation layer or another layer is coated on the support under well-controlled relative humidity; (3) a method in which the support is heat treated at not less than 100° C. immediately before an image formation layer or another layer is coated on the support, covered with a moisture shielding sheet, and then uncovered; and (4) a method in which a polyvinylidene chloride-containing layer is coated on the support as an anti-humidity layer. Two or more of these methods may be used in combination.

In the invention, the water content of the support is D′ represented by the following formula:
D′ (weight %)=(w′/W′)×100
wherein W′ represents the weight of the support in the equilibrium state at 25° C. and 60% RH, and w′ represents the weight of water contained in the support in the equilibrium state at 25° C. and 60% RH.

Polyvinylidene chloride used in the polyvinylidene chloride-containing layer keeping the water content low is preferably a vinylidene chloride copolymer. The vinylidene chloride unit content of the copolymer is preferably from 70 to 99.9% by weight, more preferably from 85 to 99% by weight, and still more preferably from 90 to 99% by weight.

A co-monomer other than vinylidene chloride in the copolymer is methacrylic acid, acrylic acid, itaconic acid, citraconic acid, or their ester derivative, acrylonitrile, methacrylonitrile, methyl acrylate, ethyl acrylate, glycidyl methacrylate, 2-hydroxyethyl methacrylate, vinyl acetate, acrylamide, or styrene.

The weight average molecular weight of the copolymer is preferably from 5,000 to 100,000, more preferably from 8,000 to 80,000, and still more preferably from 10,000 to 45,000. Herein, the weight average molecular weight can be measured according to a GPC (gel permeation chromatography) apparatus available on the market.

Arrangement of the monomer units in the copolymer is not specifically limited, and may be random or in the block form.

When the polyvinylidene chloride resin is dispersed in water, it may be latex containing polymer particles with uniform structure, or latex containing polymer particles having a core-shell structure in which composition of the core is different from that of the shell.

Examples of the vinylidene chloride copolymer will be listed below. In the examples, the copolymerization ratio in the parentheses represents weight ratio, and Mw represents weight average molecular weight.
(A) Latex of a copolymer (Mw=42,000) containing a ratio of vinylidene chloride:methyl acrylate:acrylic acid (90:9:1)
(B) Latex of a copolymer (Mw=40,000) containing a ratio of vinylidene chloride:methyl acrylate:methyl methacrylate acrylonitrile:methacrylic acid (87:4:4:4:1)
(C) Latex of a copolymer (Mw=38,000) containing a ratio of vinylidene chloride:methyl methacrylate:glycidyl methacrylate:methacrylic acid (90:6:2:2)
(D) Latex of a copolymer (Mw=44,000) containing a ratio of vinylidene chloride:ethyl methacrylate:2-hydroxyethyl methacrylate:acrylic acid (90:8:1.5:0.5)
(E) Latex of the core-shell type (containing 90% by weight of cores and 10% by weight of shells):
Cores comprised of a copolymer containing a ratio of vinylidene chloride:methyl acrylate:methyl methacrylate:acrylonitrile:acrylic acid (93:3:3:0.9:0.1),
Shells comprised of a copolymer (Mw=38,000) containing a ratio of vinylidene chloride:methyl acrylate:methyl methacrylate:acrylonitrile:acrylic acid (98:3:3:3:3)
(F) Latex of the core-shell type (containing 70% by weight of cores and 30% by weight of shells):
Cores comprised of a copolymer containing a ratio of vinylidene chloride:methyl acrylate:methyl methacrylate acrylonitrile:methacrylic acid (92.5:3:3:1:0.5),
Shells comprised of a copolymer (Mw=20,000) containing a ratio of vinylidene chloride:methyl acrylate:methyl methacrylate:acrylonitrile:methacrylic acid (90:3:3:1:3)

The polyvinylidene chloride resin can be contained in the subbing layer, the hydrophilic layer described later or the image formation layer described later each provided on the image formation layer side of the support, and is preferably provided in the subbing layer. The subbing layer may be single or plural. Each of these layers is provided on at least one side of the support with a thickness of preferably from 0.5 to 10 μm, and it is preferred that each of these layers is provided on both sides of the support with a thickness of preferably from 0.8 to 5 μm, and more preferably from 1.0 to 3 μm.

Materials used in the hydrophilic layer of the planographic printing plate material will be explained below.

Material used in the hydrophilic layer is preferably a metal oxide, and more preferably metal oxide particles.

Examples of the metal oxide particles include colloidal silica particles, an alumina sol, a titania sol and another metal oxide sol. The metal oxide particles may have any shape such as spherical, needle-like, and feather-like shape. The average particle diameter is preferably from 3 to 100 nm, and plural kinds of metal oxide each having a different size may be used in combination. The surface of the particles may be subjected to surface treatment.

The metal oxide particles can be used as a binder, utilizing its layer forming ability. The metal oxide particles are suitably used in a hydrophilic layer since they minimize lowering of the hydrophilicity of the layer as compared with an organic compound binder. Among the above-mentioned, colloidal silica is particularly preferred. The colloidal silica has a high layer forming ability under a drying condition with a relative low temperature, and can provide a good layer strength. It is preferred that the colloidal silica used in the invention is necklace-shaped colloidal silica or colloidal silica particles having an average particle diameter of not more than 20 nm, each being described later. Further, it is preferred that the colloidal silica provides an alkaline colloidal silica solution as a colloid solution.

The necklace-shaped colloidal silica to be used in the invention is a generic term of an aqueous dispersion system of spherical silica having a primary particle diameter of the order of nm. The necklace-shaped colloidal silica to be used in the invention means a “pearl-necklace-shaped” colloidal silica formed by connecting spherical colloidal silica particles each having a primary particle diameter of from 10 to 50 μm so as to attain a length of from 50 to 400 nm. The term of “pearl necklace-shaped” means that the image of connected colloidal silica particles is like to the shape of a pearl necklace. The bonding between the silica particles forming the necklace-shaped colloidal silica is considered to be —Si—O—Si—, which is formed by dehydration of —SiOH groups located on the surface of the silica particles. Concrete examples of the necklace-shaped colloidal silica include Snowtex-PS series produced by Nissan Kagaku Kogyo, Co., Ltd.

As the products, there are Snowtex-PS-S (the average particle diameter in the connected state is approximately 110 nm), Snowtex-PS-M (the average particle diameter in the connected state is approximately 120 nm) and Snowtex-PS-L (the average particle diameter in the connected state is approximately 170 nm). Acidic colloidal silicas corresponding to each of the above-mentioned are Snowtex-PS-S-O, Snowtex-PS-M-O and Snowtex-PS-L-O, respectively.

The necklace-shaped colloidal silica is preferably used in a hydrophilic layer as a porosity providing material for hydrophilic matrix phase, and porosity and strength of the layer can be secured by its addition to the layer. Among them, the use of Snowtex-PS-S, Snowtex-PS-M or Snowtex-PS-L, each being alkaline colloidal silica particles, is particularly preferable since the strength of the hydrophilic layer is increased and occurrence of background contamination is inhibited even when a lot of prints are printed.

It is known that the binding force of the colloidal silica particles is become larger with decrease of the particle diameter. The average particle diameter of the colloidal silica particles to be used in the invention is preferably not more than 20 nm, and more preferably 3 to 15 nm. As above-mentioned, the alkaline colloidal silica particles show the effect of inhibiting occurrence of the background contamination. Accordingly, the use of the alkaline colloidal silica particles is particularly preferable.

Examples of the alkaline colloidal silica particles having the average particle diameter within the foregoing range include Snowtex-20 (average particle diameter: 10 to 20 nm), Snowtex-30 (average particle diameter: 10 to 20 nm), Snowtex-40 (average particle diameter: 10 to 20 nm), Snowtex-N (average particle diameter: 10 to 20 nm), Snowtex-S (average particle diameter: 8 to 11 nm) and Snowtex-XS (average particle diameter: 4 to 6 nm), each produced by Nissan Kagaku Co., Ltd.

The colloidal silica particles having an average particle diameter of not more than 20 nm, when used together with the necklace-shaped colloidal silica as described above, is particularly preferred, since appropriate porosity of the layer is maintained and the layer strength is further increased.

The ratio of the colloidal silica particles having an average particle diameter of not more than 20 nm to the necklace-shaped colloidal silica is preferably from 95/5 to 5/95, more preferably from 70/30 to 20/80, and most preferably from 60/40 to 30/70.

The hydrophilic layer of the printing plate material in the invention can contain porous metal oxide particles with a particle diameter of less than 1 μm as porosity providing material. Examples of the porous metal oxide particles include porous silica particles, porous aluminosilicate particles or zeolite particles as described later.

The porous silica particles are ordinarily produced by a wet method or a dry method. By the wet method, the porous silica particles can be obtained by drying and pulverizing a gel prepared by neutralizing an aqueous silicate solution, or pulverizing the precipitate formed by neutralization. By the dry method, the porous silica particles are prepared by combustion of silicon tetrachloride together with hydrogen and oxygen to precipitate silica.

The porosity and the particle diameter of such particles can be controlled by variation of the production conditions. The porous silica particles prepared from the gel by the wet method is particularly preferred.

The porous aluminosilicate particles can be prepared by the method described in, for example, JP O.P.I. No. 10-71764. Thus prepared aluminosilicate particles are amorphous complex particles synthesized by hydrolysis of aluminum alkoxide and silicon alkoxide as the major components. The particles can be synthesized so that the ratio of alumina to silica in the particles is within the range of from 1:4 to 4:1. Complex particles composed of three or more components prepared by an addition of another metal alkoxide may also be used in the invention. In such a particle, the porosity and the particle diameter can be controlled by adjustment of the production conditions.

The porosity of the particles is preferably not less than 1.0 ml/g, more preferably not less than 1.2 ml/g, and most preferably of from 1.8 to 2.5 ml/g, in terms of pore volume before the dispersion. The pore volume is closely related to water retention of the coated layer. As the pore volume increases, the water retention is increased, stain is difficult to occur, and water tolerance is high. Particles having a pore volume of more than 2.5 ml/g are brittle, resulting in lowering of durability of the layer containing them. Particles having a pore volume of less than 1.0 ml/g may provide insufficient printing property.

As porosity providing material, zeolite can be used.

Zeolite is a crystalline aluminosilicate, which is a porous material having voids of a regular three dimensional net work structure and having a pore size of 0.3 to 1 nm. Natural and synthetic zeolites are expressed by the following formula.
(M¹, (M²)_{1/2})ₘ(AlₘSiₙO₂₍ₘ₊ₙ₎).xH₂O

In the above, M¹ and M² are each exchangeable cations. Examples of M¹ include Li⁺, Na⁺, K⁺, Tl⁺, Me₄N⁺ (TMA), Et₄N⁺ (TEA) , Pr₄N⁺ (TPA), C₇H₁₅N²⁺, and C₈H₁₆N⁺, and examples of M² include Ca²⁺, Mg²⁺, Ba²⁺, Sr²⁺ and (C₈H₁₈N)₂²⁺. Relation of n and m is n≧m, and consequently, the ratio of m/n, or that of Al/Si is not more than 1. A higher Al/Si ratio shows a higher content of the exchangeable cation, and a higher polarity, resulting in higher hydrophilicity. The Al/Si ratio is within the range of preferably from 0.4 to 1.0, and more preferably 0.8 to 1.0. x is an integer.

Synthetic zeolite having a stable Al/Si ratio and a sharp particle diameter distribution is preferably used as the zeolite particles to be used in the invention. Examples of such zeolite include Zeolite A: Na₁₂(Al₁₂Si₁₂O₄₈).27H₂O; Al/Si=1.0, Zeolite X: Na₈₆(Al₈₆Si₁₀₆O₃₈₄).264H₂O; Al/Si=0.811, and Zeolite Y: Na₅₆(Al₅₆Si₁₃₆O₃₈₄).250H₂O; Al/Si=0.412.

Containing the porous zeolite particles having an Al/Si ratio within the range of from 0.4 to 1.0 in the hydrophilic layer greatly raises the hydrophilicity of the hydrophilic layer itself, whereby contamination in the course of printing is inhibited and the water retention latitude is also increased. Further, contamination caused by a finger mark is also greatly reduced. When Al/Si is less than 0.4, the hydrophilicity is insufficient and the above-mentioned improving effects are lowered.

The hydrophilic layer of the printing plate material in the invention can contain layer structural clay mineral particles as a metal oxide. Examples of the layer structural clay mineral particles include a clay mineral such as kaolinite, halloysite, talk, smectite such as montmorillonite, beidellite, hectorite and saponite, vermiculite, mica and chlorite; hydrotalcite; and a layer structural polysilicate such as kanemite, makatite, ilerite, magadiite and kenyte. Among them, ones having a higher electric charge density of the unit layer are higher in the polarity and in the hydrophilicity. Preferable charge density is not less than 0.25, more preferably not less than 0.6. Examples of the layer structural mineral particles having such a charge density include smectite having a negative charge density of from 0.25 to 0.6 and bermiculite having a negative charge density of from 0.6 to 0.9. Synthesized fluorinated mica is preferable since one having a stable quality, such as the particle diameter, is available. Among the synthesized fluorinated mica, swellable one is preferable and one freely swellable is more preferable.

An intercalation compound of the foregoing layer structural mineral particles such as a pillared crystal, or one treated by an ion exchange treatment or a surface treatment such as a silane coupling treatment or a complication treatment with an organic binder is also usable.

The planar structural mineral particles are preferably in the plate form, and have an average particle diameter (an average of the largest particle length) of less than 1 μm, and an average aspect ratio (the largest particle length/the particle thickness) of preferably not less than 50, in a state contained in the layer including the case that the particles are subjected to a swelling process and a dispersing layer-separation process. When the particle diameter is within the foregoing range, continuity to the parallel direction, which is a trait of the layer structural particle, and softness, are given to the coated layer so that a strong dry layer in which a crack is difficult to be formed can be obtained. The coating solution containing the layer structural clay mineral particles in a large amount can minimize particle sedimentation due to a viscosity increasing effect. The particle diameter falling outside the above range may produce non-uniformity in the coated layer, resulting in lowering strength of the layer. The aspect ratio less than the lower limit of the above range reduces the number of the particles relative to the addition amount, and lowers viscosity increasing effect, resulting in lowering of particle sedimentation resistance.

The content of the layer structural clay mineral particles is preferably from 0.1 to 30% by weight, and more preferably from 1 to 10% by weight based on the total weight of the layer. Particularly, the addition of the swellable synthesized fluorinated mica or smectite is effective if the adding amount is small. The layer structural clay mineral particles may be added in the form of powder to a coating liquid, but it is preferred that gel of the particles which is obtained by being swelled in water, is added to the coating liquid in order to obtain a good dispersity according to an easy coating liquid preparation method which requires no dispersion process comprising dispersion due to media.

An aqueous solution of a silicate is also usable as another additive to the hydrophilic matrix phase in the invention. An alkali metal silicate such as sodium silicate, potassium silicate or lithium silicate is preferable, and the ratio SiO₂/M₂O is preferably selected so that the pH value of the coating liquid after addition of the silicate does not exceed 13 in order to prevent dissolution of the porous metal oxide particles or the colloidal silica particles.

An inorganic polymer or an inorganic-organic hybrid polymer prepared by a sol-gel method employing a metal alkoxide. Known methods described in S. Sakka “Application of Sol-Gel Method” or in the publications cited in the above publication can be applied to prepare the inorganic polymer or the inorganic-organic hybrid polymer by the sol-gel method.

The hydrophilic layer may contain a water soluble resin. Examples of the water soluble resin include polysaccharides, polyethylene oxide, polypropylene oxide, polyvinyl alcohol, polyethylene glycol (PEG), polyvinyl ether, a styrene-butadiene copolymer, a conjugation diene polymer latex of methyl methacrylate-butadiene copolymer, an acryl polymer latex, a vinyl polymer latex, polyacrylamide, and polyvinyl pyrrolidone. In the invention, polysaccharides are preferred.

As the polysaccharide, starches, celluloses, polyuronic acid and pullulan can be used. Among them, a cellulose derivative such as a methyl cellulose salt, a carboxymethyl cellulose salt or a hydroxyethyl cellulose salt is preferable, and a sodium or ammonium salt of carboxymethyl cellulose is more preferable. These polysaccharides can form a preferred surface shape of the hydrophilic layer.

The surface of the hydrophilic layer preferably has a convexoconcave structure having a pitch of from 0.1 to 20 μm such as the grained aluminum surface of an aluminum PS plate. The water retention ability and the image maintaining ability are raised by such a convexoconcave structure of the surface. Such a convexoconcave structure can also be formed by adding in an appropriate amount a filler having a suitable particle diameter to the coating liquid of the hydrophilic layer. However, the convexoconcave structure is preferably formed by coating a coating liquid for the hydrophilic layer containing the alkaline colloidal silica and the water-soluble polysaccharide so that the phase separation occurs at the time of drying the coated liquid, whereby a structure is obtained which provides a good printing performance.

The shape of the convexoconcave structure such as the pitch and the surface roughness thereof can be suitably controlled by the kinds and the adding amount of the alkaline colloidal silica particles, the kinds and the adding amount of the water-soluble polysaccharide, the kinds and the adding amount of another additive, a solid concentration of the coating liquid, a wet layer thickness or a drying condition.

It is preferred that the water soluble resin is contained in the hydrophilic layer in such a state that at least a part of the water soluble resin is capable of being dissolved in water. This is because even the water soluble resin, when cross-linked with a cross-linking agent, is water insoluble, which lowers its hydrophilicity and printing properties.

A cationic resin may also be contained in the hydrophilic layer. Examples of the cationic resin include a polyalkylene-polyamine such as a polyethyleneamine or polypropylenepolyamine or its derivative, an acryl resin having a tertiary amino group or a quaternary ammonium group and diacrylamine. The cationic resin may be added in a form of fine particles. Examples of such particles include the cationic microgel described in Japanese Patent O.P.I. Publication No. 6-161101.

A water-soluble surfactant may be added for improving the coating ability of the coating liquid for the hydrophilic layer in the invention. A silicon atom-containing surfactant and a fluorine atom-containing surfactant are preferably used. The silicon atom-containing surfactant is especially preferred in that it minimizes printing contamination. The content of the surfactant is preferably from 0.01 to 3% by weight, and more preferably from 0.03 to 1% by weight based on the total weight of the hydrophilic layer (or the solid content of the coating liquid).

The hydrophilic layer in the invention can contain a phosphate. Since a coating liquid for the hydrophilic layer is preferably alkaline, the phosphate to be added to the hydrophilic layer is preferably sodium phosphate or sodium monohydrogen phosphate. The addition of the phosphate provides improved reproduction of dots at shadow portions. The content of the phosphate is preferably from 0.1 to 5% by weight, and more preferably from 0.5 to 2% by weight in terms of amount excluding hydrated water.

The hydrophilic layer can contain a light-to-heat conversion material described later. The light-to-heat conversion material, when particles, is preferably ones with a particle diameter of less than 1 μm.

In the invention, inorganic particles with a particle diameter of not less than 1 μm or inorganic material-coated particles with a particle diameter of not less than 1 μm are preferred. Examples of the inorganic particles include particles of known metal oxides such silica, alumina, titania and zirconia. However, porous metal oxide particles are preferably used in order to prevent sedimentation of the particles in the coating solution.

As the porous particles, porous silica particles or porous aluminosilicate particles as described above can be preferably used.

As the inorganic material-coated particles, there are, for example, particles in which organic particles such as particles of PMMA or polystyrene as core particles are coated with inorganic particles with a particle diameter smaller that that of the core particles. The particle diameter of the inorganic particles is preferably from 1/10 to 1/100 of that of the core particles. As the inorganic particles, particles of known metal oxides such silica, alumina, titania and zirconia can be used.

Various coating methods can be used, but a dry process is preferred which core particles collide with particles for coating at high speed in air as in a hybridizer to push the particles for coating in the core particle surface and fix, whereby the core particles are coated with the particles for coating.

Particles, in which the organic core particles are plated with metal, can be used. As such particles, there is, for example, “Micropearl AU”, produced by SEKISUI KAGAKU KOGYO Co, Ltd., in which resin particles are plated with gold.

The particle diameter of the inorganic particles or the inorganic material-coated particles above is preferably from 1 to 10 μm, more preferably from 1.5 to 8 μm, and still more preferably from 2 to 6 μm. The particles diameter exceeding 10 μm results in problem of lowering dissolution of formed images or contaminating a blanket.

The content of the particles described above with a particle diameter of not less than 1 μm in the hydrophilic layer is preferably from 1 to 50% by weight, and more preferably from 5 to 40% by weight. In the hydrophilic layer, the content of carbon-containing materials such as organic resins or carbon black is preferably low in increasing hydrophilicity. The content of the carbon-containing materials in the hydrophilic layer is preferably less than 9% by weight, and more preferably less than 5% by weight.

The thickness of the hydrophilic layer is preferably from 0.05 to 5 g/m², more preferably from 0.1 to 4 g/m², and most preferably from 0.3 to 3.5 g/m².

In the invention, a second hydrophilic layer may be provided under the hydrophilic layer described above, and when the second hydrophilic layer is provided, materials used in the second hydrophilic layer are the same materials as in the hydrophilic layer described above.

However, the second hydrophilic layer, when it is porous, is less advantageous. Since the second hydrophilic layer is preferably non-porous in view of strength of the layer, the porosity providing agent content of the second hydrophilic layer is preferably lower than that of the hydrophilic layer described above. It is more preferable that the second hydrophilic layer contains no porosity providing agent.

The content of the particles with a particle diameter of not less than 1 μm in the second hydrophilic layer is preferably from 1 to 50% by weight, and more preferably from 5 to 40% by weight.

Like the hydrophilic layer above, the content of carbon-containing materials such as the organic resins or carbon black in the second hydrophilic layer is preferably lower in increasing hydrophilicity of the second hydrophilic layer. The total content of these materials in the under layer is preferably less than 9% by weight, and more preferably less than 5% by weight.

In the invention, the image formation layer preferably contains heat melting particles and/or heat fusible particles.

The heat melting particles used in the invention are particularly particles having a low melt viscosity, which are particles formed from materials generally classified into wax. The materials preferably have a softening point of from 40° C. to 120° C. and a melting point of from 60° C. to 150° C., and more preferably a softening point of from 40° C. to 100° C. and a melting point of from 60° C. to 120° C. The melting point less than 60° C. has a problem in storage stability and the melting point exceeding 300° C. lowers ink receptive sensitivity.

Materials usable include paraffin, polyolefin, polyethylene wax, microcrystalline wax, and fatty acid wax. The molecular weight thereof is approximately from 800 to 10,000. A polar group such as a hydroxyl group, an ester group, a carboxyl group, an aldehyde group and a peroxide group may be introduced into the wax by oxidation to increase the emulsification ability. Moreover, stearoamide, linolenamide, laurylamide, myristylamide, hardened cattle fatty acid amide, parmitylamide, oleylamide, rice bran oil fatty acid amide, palm oil fatty acid amide, a methylol compound of the above-mentioned amide compounds, methylenebissteastearoamide and ethylenebissteastearoamide may be added to the wax to lower the softening point or to raise the working efficiency. A cumarone-indene resin, a rosin-modified phenol resin, a terpene-modified phenol resin, a xylene resin, a ketone resin, an acryl resin, an ionomer and a copolymer of these resins may also be usable.

Among them, polyethylene, microcrystalline wax, fatty acid ester and fatty acid are preferably contained. A high sensitive image formation can be performed since these materials each have a relative low melting point and a low melt viscosity. These materials each have a lubrication ability. Accordingly, even when a shearing force is applied to the surface layer of the printing plate precursor, the layer damage is minimized, and resistance to stain which may be caused by scratch is further enhanced.

The heat melting particles are preferably dispersible in water. The average particle diameter thereof is preferably from 0.01 to 10 ηm, and more preferably from 0.1 to 3 μm, in view of on-press developability, resistance to background contamination, or dissolving power.

The composition of the heat melting particles may be continuously varied from the interior to the surface of the particles. The particles may be covered with a different material. Known microcapsule production method or sol-gel method can be applied for covering the particles. The heat melting particle content of the layer is preferably 1 to 90% by weight, and more preferably 5 to 80% by weight based on the total layer weight.

The heat fusible particles in the invention include thermoplastic hydrophobic polymer particles. Although there is no specific limitation to the upper limit of the softening point of the thermoplastic hydrophobic polymer, the softening point is preferably lower than the decomposition temperature of the polymer. The weight average molecular weight (Mw) of the thermoplastic hydrophobic polymer is preferably within the range of from 10,000 to 1,000,000.

Examples of the polymer consisting the polymer particles include a diene (co)polymer such as polypropylene, polybutadiene, polyisoprene or an ethylene-butadiene copolymer; a synthetic rubber such as a styrene-butadiene copolymer, a methyl methacrylate-butadiene copolymer or an acrylonitrile-butadiene copolymer; a (meth)acrylate (co)polymer or a (meth)acrylic acid (co)polymer such as polymethyl methacrylate, a methyl methacrylate-(2-ethylhexyl)acrylate copolymer, a methyl methacrylate-methacrylic acid copolymer, or a methyl acrylate-(N-methylolacrylamide); polyacrylonitrile; a vinyl ester (co)polymer such as a polyvinyl acetate, a vinyl acetate-vinyl propionate copolymer and a vinyl acetate-ethylene copolymer, or a vinyl acetate-2-hexylethyl acrylate copolymer; and polyvinyl chloride, polyvinylidene chloride, polystyrene and a copolymer thereof. Among them, the (meth)acrylate polymer, the (meth)acrylic acid (co)polymer, the vinyl ester (co)polymer, the polystyrene and the synthetic rubbers are preferably used.

The polymer particles may be prepared from a polymer synthesized by any known method such as an emulsion polymerization method, a suspension polymerization method, a solution polymerization method and a gas phase polymerization method. The particles of the polymer synthesized by the solution polymerization method or the gas phase polymerization method can be produced by a method in which an organic solution of the polymer is sprayed into an inactive gas and dried, and a method in which the polymer is dissolved in a water-immiscible solvent, then the resulting solution is dispersed in water or an aqueous medium and the solvent is removed by distillation. In both of the methods, a surfactant such as sodium lauryl sulfate, sodium dodecylbenzenesulfate or polyethylene glycol, or a water-soluble resin such as poly(vinyl alcohol) may be optionally used as a dispersing agent or stabilizing agent.

The heat fusible particles are preferably dispersible in water. The average particle diameter of the heat fusible particles is preferably from 0.01 to 10 μm, and more preferably from 0.1 to 3 μm, in view of on-press developability, resistance to background contamination or dissolving power.

Further, the composition of the heat fusible particles may be continuously varied from the interior to the surface of the particles. The particles may be covered with a different material. As a covering method, known methods such as a microcapsule method and a sol-gel method are usable. The heat fusible particle content of the layer is preferably from 1 to 90% by weight, and more preferably from 5 to 80% by weight based on the total weight of the layer.

In the invention, the image formation layer containing heat melting particles and/or heat fusible particles can further contain a water soluble material. When the image formation layer at unexposed portions is removed on a press with dampening water or ink, the water soluble material makes it possible to easily remove the layer.

Regarding the water soluble material, those described above as water soluble materials to be contained in the hydrophilic layer can be used. The image formation layer in the invention preferably contains saccharides, and more preferably contains oligosaccharides. Since the oligosaccharides are easily dissolved in water, removal on a press of unexposed portions of an oligosaccharide-containing layer can be easily carried out dissolving the saccharide in water. The removal does not require a specific system, and can be carried out conducting the same manner as in the beginning of printing of a conventional PS plate, which does not increase loss of prints at the beginning of printing. Use of the oligosaccharide does not lower hydrophilicity of the hydrophilic layer and can maintain good printing performance of the hydrophilic layer.

The oligosaccharide is a water-soluble crystalline substance generally having a sweet taste, which is formed by a dehydration condensation reaction of plural monosaccharide molecules. The oligosaccharide is one kind of o-glycoside having a saccharide as the aglycon. The oligosaccharide is easily hydrolyzed by an acid to form a monosaccharide, and is classified according to the number of monosaccharide molecules of the resulting hydrolysis compounds, for example, into disaccharide, trisaccharide, tetrasaccharide, and pentasscharide. The oligosaccharide referred to in the invention means di- to deca-saccharides.

The oligosaccharide is classified into a reducing oligosaccharide and a non-reducing oligosaccharide according to presence or absence of a reducing group in the molecule. The oligosaccharide is also classified into a homo-oligosaccharide composed of the same kind of monosaccharide and a hetero-oligosaccharide composed of two or more kinds of monosaccharides. The oligosaccharide naturally exists in a free state or a glycoside state. Moreover, various oligosaccharides are formed by glycosyl transition by action of an enzyme.

The oligosaccharide frequently exists in a hydrated state in an ordinary atmosphere. The melting points of the hydrated one and anhydrous one are different from each other.

In the invention, the layer containing a saccharide is preferably formed coating an aqueous coating solution containing the saccharide on a support. When an oligossccharide in the layer formed from the aqueous coating solution is one capable of forming a hydrate, the melting point of the oligosaccharide is that of its hydrate. Since the oligosaccharides, having a relatively low melting point, also melt within the temperature range at which heat melting particles melt or heat fusible particles fuse, they do not cause image formation inhibition resulting from permeation of the heat melting particles into the porous hydrophilic layer and/or fusion adhesion of the heat fusible particles to the hydrophilic layer.

Among the oligosaccharides, trehalose with comparatively high purity is available on the market, and has an extremely low hygroscopicity, although it has high water solubility, providing excellent storage stability and excellent development property on a printing press.

When oligosaccharide hydrates are heat melted to remove the hydrate water and solidified, the oligosaccharide is in a form of anhydride for a short period after solidification. Trehalose is characterized in that a melting point of trehalose anhydride is not less than 100° C. higher that that of trehalose hydrate. This characteristics provides a high melting point and reduced heat fusibility at exposed portions of the trehalose-containing layer immediately after heat-fused by infrared ray exposure and re-solidified, preventing image defects at exposure such as banding from occurring. In order to attain the object of the invention, trehalose is preferable among oligosaccharides.

The oligosaccharide content of the layer is preferably from 1 to 90% by weight, and more preferably from 10 to 80% by weight, based on the total weight of the layer.

The thickness of the image formation layer is preferably from 0.05 to 3 g/m², more preferably from 0.1 to 2.5 g/m², and most preferably from 0.4 to 1.0 g/m².

<Image Formation>

In the invention, image formation on the planographic printing plate material of the invention can be carried out by applying heat, and is carried out preferably by infrared laser exposure.

Exposure applied in the invention is preferably scanning exposure, which is carried out employing a laser which can emit light having a wavelength of infrared and/or near-infrared regions, that is, a wavelength of from 700 to 1500 nm. As the laser, a gas laser can be used, but a semi-conductor laser, which emits light having a near-infrared region wavelength, is preferably used.

A device suitable for the scanning exposure in the invention may be any device capable of forming an image on the printing plate precursor according to image signals from a computer employing a semi-conductor laser.

Generally, the following scanning exposure processes are mentioned.

(1) A process in which a plate precursor provided on a fixed horizontal plate is scanning exposed in two dimensions, employing one or several laser beams.

(2) A process in which the surface of a plate precursor provided along the inner peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

(3) A process in which the surface of a plate precursor provided along the outer peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

In the invention, the process (3) above is preferable, and especially preferable when a printing plate precursor mounted on a plate cylinder of a printing press is scanning exposed.

In the invention, an image can be formed by imagewise providing a lipophilic material directly on the hydrophilic layer surface of the planographic printing plate material of the invention.

As one of the methods of imagewise providing the lipophilic material, there is a method of employing a known thermal transfer process. For example, there is a method of imagewise transferring a heat fusible ink of an ink ribbon having a heat fusible ink layer onto the surface of the hydrophilic layer employing a thermal head.

There is also a method of mounting the printing plate precursor on an exposure drum of a digital proof apparatus employing an infrared laser heat fusion transfer process, with the hydrophilic layer outwardly, further providing an ink sheet having an ink layer on the hydrophilic layer so that the ink layer contacts the hydrophilic layer, and then imagewise exposing the ink sheet by infrared laser to imagewise transfer a heat fusible ink of the ink layer onto the surface of the hydrophilic layer. In this case, a light heat conversion material may be contained in the hydrophilic layer of the printing plate precursor, in the ink sheet, or in both hydrophilic layer and ink sheet.

An image, which has been formed on the hydrophilic layer of the printing plate precursor employing a heat fusible ink, can be more firmly adhered to the hydrophilic layer by heating the printing plate precursor. When the hydrophilic layer contains a light heat conversion material, the heating can be carried out employing an infrared laser exposure or a flush exposure such as a xenon lamp exposure.

As another method of imagewise providing the lipophilic material, there is a method of employing a known ink jet process. In this case, inks used include a lipophilic ink disclosed in Japanese Patent Publication No. 2995075, a hot melt ink disclosed in Japanese Patent O.P.I. Publication No. 10-24550, a lipophilic ink, in which hydrophobic resin particles being a solid at ordinary temperature are dispersed, disclosed in Japanese Patent O.P.I. Publication No. 10-157053, and an aqueous ink, in which hydrophobic thermoplastic resin particles being a solid at ordinary temperature are dispersed. In the invention, a radiation curable ink is preferably used.

The radiation curable ink in the invention contains at least a polymerizable compound, and can contain a colorant to produce a visible image. As the colorant, a colorant such as a dye or pigment, which is soluble or dispersible in a main polymerizable compound, can be used.

When pigment is used, dispersion treatment is carried out, since its degree of dispersion has a great influence on a color density. Devices for dispersing pigment include a ball mill, an atriter, a roll mill, an agitator, a Henschel mixer, a colloid mill, a supersonic homogenizer, a pearl mill, a wet jet mill, and a paint shaker. When pigment is dispersed, a dispersant can be added. As the dispersant, a polymer dispersant is preferably used, and preferred examples of the polymer dispersant include Solsperse series produced by Zeneca Co., Ltd. As an auxiliary dispersant, a synergist according to kinds of dispersant can be used. An addition amount of the dispersant or auxiliary dispersant is preferably from 1 to 50 parts by weight based on 100 parts by weight of pigment used. A dispersion medium is a solvent or a polymerizable compound. It is preferred that the radiation curable ink used in the invention does not contain a solvent, since it is hardened immediately after jetted to an image recording medium. The residual solvent in the hardened image results in lowering of solvent resistance and problem of VOC. The dispersion medium is preferably a polymerizable compound, and more preferably a monomer having the lowest viscosity among monomers.

Pigment, a dispersant, a dispersion medium, dispersing conditions and a filtration condition are preferably determined to obtain pigment particles with an average particle diameter of preferably from 0.08 to 0.3 μm, a maximum particle diameter of from 0.3 to 10 μm, and preferably from 0.3 to 3 μm. The above range of the particle diameter can prevent clogging of an ink head nozzle, and provide excellent ink storage stability, ink transparency and ink curing sensitivity. The colorant content of ink is preferably from 0.1 to 10% by weight.

The colorant content of ink is preferably from 0.1 to 10% by weight.

As the polymerizable compound, there are known radical polymerizable compounds such as photo-curable compounds used in the photopolymerizable composition disclosed in Japanese Patent O.P.I. Publication Nos. 7-159983, 8-224982, and 10-863 and Japanese Patent Publication No. 7-31399, or cation polymerization photo-curable compounds. Recently, cation polymerization photo-curable resins sensitive to light having a wavelength identical to or longer than that of visible light are disclosed in Japanese Patent O.P.I. Publication Nos. 6-43633 and 8-324137.

The radical polymerizable compound is an ethylenically unsaturated compound capable of being polymerized by a radical, and is any-compound, as long as it has at least one ethylenically unsaturated double bond in the molecule. The radical polymerizable compound may have any structure in the form of monomer, oligomer or polymer. The radical polymerizable compound can be used singly or in combination of two or more kinds in any content ratio, according to the objects of the usage. A polyfunctional compound having at least two functional groups is preferable to a monofunctional compound. Use of two kinds or more of the polyfunctional compound is more preferable in controlling physical properties or performance of ink.

The ethylenically unsaturated compound, which is capable of being polymerized by a radical, includes an unsaturated carboxylic acid such as acrylic acid, methacrylic acid, itaconic acid, crotonic acid, isocrotonic acid, or maleic acid or its salt, ester, urethane, amide or anhydride; acrylonitrile; styrene; unsaturated polyesters; unsaturated polyethers; unsaturated polyamides; and unsaturated polyurethanes. The examples include an acrylic acid derivative such as 2-ethylhexyl acrylate, 2-hydroxyethyl acrylate, butoxyethyl acrylate, carbitol acrylate, cyclohexyl acrylate, tetrahydrofurfuryl acrylate, benzyl acrylate, bis(4-acryloxypolyethoxyphenyl)propane, neopentyl glycol diacrylate, 1,6-hexanediol diacrylate, ethylene glycol diacrylate, diethylene glycol diacrylate, triethylene glycol diacrylate, tetraethylene glycol diacrylate, polyethylene glycol diacrylate, polypropylene glycol diacrylate, pentaerythritol triacrylate, pentaerythritol tetraacrylate, dipentaerythritol tetraacrylate, trimethylolpropane triacrylate, tetramethylolmethane tetraacrylate, oligo ester acrylate, N-methylol acryl amide, diacetone acryl amide, or epoxy acrylate; a methacrylic acid derivative such as methyl methacrylate, n-butyl methacrylate, 2-ethylhexyl methacrylate, lauryl methacrylate, allyl methacrylate, glycidyl methacrylate, benzyl methacrylate, dimethylaminomethyl methacrylate, 1,6-hexanediol dimethacrylate, ethylene glycol dimethacrylate, triethylene glycol dimethacrylate, polyethylene glycol dimethacrylate, polypropylene glycol dimethacrylate, trimethylolethane trimethacrylate, trimethylolpropane trimethacrylate, or 2,2-bis(4-methacryloxy-polyethoxyphenyl)propane; an allyl compound such as allyl glycidyl ether, diallyl phthalate or triallyl trimellitate; and radical polymerizable or crosslinkable monomers, oligomers or polymers described in S. Yamashita et al., “Crosslinking agent Handbook”, Taisei Co., Ltd. (1981), K. Kato et al., “UV, EB Hardenable Handbook (Materials)”, Kobunshi Kankokai (1985), Radotek Kenkyukai, “UV, EB Hardening Technology, Application and Market”, pp. 79, CMC Co. Ltd. (1989), and E. Takiyama, “Polyester Resin Handbook”, Nikkan Kyogyo Shinbunsha (1988). The content of the radical polymerizable compound in ink is preferably from 1 to 97% by weight, and more preferably from 30 to 95% by weight.

Listed as cation polymerizable photo-curable resins may be a monomer (of mainly an epoxy type) which undergoes polymerization due to cationic polymerization, a UV curing prepolymer-of an epoxy type, and a prepolymer having at least two epoxy groups in one molecule. Listed as such prepolymers may be, for example, alicyclic polyepoxides, polyglycidyl esters of polybasic acids, polyglycidyl ethers of polyhydric alcohols, polyglycidyl ethers of polyoxyalkylene glycol, polyglycidyl ethers of aromatic polyols, hydrogenated compounds of polyglycidyl ethers of aromatic polyols, urethane polyepoxy compounds and epoxylated polybutadine. Types of these polymers may be employed individually or in combinations of two or more types.

In the polymerizable compound in the invention, a (meth)acrylate type monomer or prepolymer, an epoxy type monomer or prepolymer, or a urethane type monomer or prepolymer, is preferably used. More preferred examples of the polymerizable compound include 2-ethylhexyl-diglycolacrylate, 2-hydroxy-3-phenoxypropyl acrylate, 2-hydroxybutyl acrylate, hydroxypivalic acid neopentylglycol acrylate, 2-acryloyloxyethylphtharic acid, methoxy-polyethylene glycol acrylate, tetramethylolmethane triacrylate, 2-acryloyloxyethyl-2-hydroxyethylphtharic acid, dimethyloltricyclodecan diacrylate, ethoxylated phenyl acrylate, 2-acryloyloxyethylsuccinic acid, nonylphenol EO adduct acrylate, modified glycerin triacrylate, bisphenol A diglycidyl ether acrylic acid adduct, modified bisphenol A diacrylate, phenoxypolyethylene glycol acrylate, 2-acryloyloxyethylhexahydrophthalic acid, bisphenol A PO adduct diacrylate, bisphenol A EO adduct diacrylate, dipentaerythritol hexacrylate, pentaerythritol triacrylate, tolylenediisocyanateerethane prepolymer, lactone-modified flexible acrylate, butoxyethyl acrylate, propylene, glycol diglycidyl ether acrylic acid adduct, pentaerythritol triacrylate hexamethylenediisocyanate urethane prepolymer, 2-hydroxyethyl acrylate, methoxydipropylene glycol acrylate, ditrimethylolpropane tetracrylate, pentaerythritol triacrylate hexamethylenediisocyanate urethane prepolymer, stearyl acrylate, isoamyl acrylate, isomyristyl acrylate, and isostearyl acrylate.

These acrylate compounds are less irritative or susceptible to skin (less poisoned), as compared to conventional polymerizable compound used in UV curable ink. These can lower a viscosity of ink, and can provide stable ink ejecting property, good polymerization sensitivity, and good adhesion to an ink recording medium. The content of the above compound in ink is from 20 to 95% by weight, preferably 50 to 95% by weight, and more preferably 70 to 95% by weight.

The monomers described above, if low molecular weight compounds, are less irritative, and have high reactivity, low viscosity, and excellent permeation or adhesion to the hydrophilic layer.

In order to improve sensitivity, bleeding and adhesion to the hydrophilic layer, a combined use of the monoacryltes described above and a polyfunctional acrylate monomer or polyfunctional acrylate oligomer having a molecular weight of not less than 400, and more preferably not less than 500 is preferred. As oligomers maintaining safety and further improving sensitivity, bleeding and adhesion to the hydrophilic layer, epoxyacrylate oligomer and urethaneacrylate oligomer are preferred.

A combine use of monoacrylates selected from the compounds described above and a polyfunctional acrylate monomer or oligomer is preferred in providing a flexible film, as well as high adhesion and film strength. The monoacrylates are preferably stearyl acrylate, isoamyl acrylate, isomyristyl acrylate, and isostearyl acrylate in providing high sensitivity and low shrinkage, preventing bleeding, minimizing ink odor of printed matter, and reducing cost.

Methacrylates are less irritative to skin than acrylates, but there are no substantial difference between those monomers with respect to susceptibility. Methacrylates have a sensitivity lower than acrylates, and are not suitable to use. However, methacrylate having high sensitivity and low susceptibility can be used. Alkoxyacrylates of the above monomers have problems with respect to sensitivity, bleeding, odor or an exposure source. It is preferred that the content of the alkoxyacrylates is less than 70 parts by weight, and the rest is another acrylate.

The ink used in the invention can contain other additives, as necessary.

When an electron beam or X ray is used as an exposure source, initiators are not needed, but when UV light, visible light or infrared light is used as a light source, radical polymerization initiators, auxiliary initiators, or sensitizing dyes are used according to the respective wavelength of light. The addition amount of these compounds is 1 to 10 parts by weight based on the weight of ink. The initiators include conventional initiators, but are selected from those soluble in the above polymerizable compounds. Examples of the initiators include xanthone or isoxanthone compounds, benzophenone compounds, quinone compounds, and phosphine oxides.

Ink can contain polymerization inhibitors in an amount of 200 to 20000 ppm in order to increase ink storage stability. It is preferred that the ink used in the invention is heated to 40 to 80° C. to lower its viscosity, and ejected. Accordingly, polymerization inhibitors are preferably added to ink in order to prevent clogging of an ink head nozzle.

Besides the above, a surfactant, a leveling agent, a matting agent, and a polyester resin, a polyurethane resin, a vinyl resin, an acryl resin, a rubber resin or waxes for adjusting film properties is optionally added to ink. In order to increase adhesion to a recording medium such as a polyolefin or PET film, a tackifier which does not inhibit polymerization is preferably added to ink. Its typical examples include a high molecular weight sticky polymer disclosed on pages 5 and 6 of Japanese Patent O.P.I. Publication No. 2001-49200 (a copolymer comprising an ester of (meth)acrylic acid with alcohol having an alkyl group having 1 to 20 carbon atoms, an ester of (meth)acrylic acid with an alicyclic alcohol having 3 to 14 carbon atoms, or an ester of (meth)acrylic acid with an aromatic alcohol having 6 to 14 carbon atoms), and low molecular weight stickiness providing resins having a polymerizable unsaturated bond.

In order to improve adhesion to the hydrophilic layer, addition of a minute amount of an organic solvent is effective. The addition of the organic solvent in an amount within the range which does not produce problems in solvent resistance or VOC is effective, and the content of the organic solvent in ink is from 0.1 to 5% and preferably from 0.1 to 3%.

As a means for minimizing lowering of sensitivity due to shielding effect of the colorant used, radical cation hybrid curable ink such as a combination of cation polymerization monomer and an initiator having a long lifetime can be used.

The composition of ink is determined to provide an ink viscosity of preferably from 7 to 30 mPa.s, and more preferably from 7 to 20 mPa.s at an ink ejecting temperature in view of ink ejecting property. The ink viscosity is preferably from 35 to 500 mPa.s, and more preferably from 35 to 200 mPa.s at 25° C. Increase of ink viscosity at room temperature can prevent ink from permeating into a porous layer of an ink recording medium, reduce an uncured monomer and malodor, minimize bleeding, and improve image quality. A viscosity less than 35 mPa.s does not minimize bleeding, and a viscosity exceeding 500 mPa.s causes problem of ink delivery.

The surface tension of ink is preferably from 200 to 300 μN/cm, and more preferably from 230 to 280 μN/cm. A surface tension less than 200 μN/cm has problem in bleeding or permeation, and a surface tension exceeding 300 μN/cm has problem in wettability.

The hydrophilic layer, under layer or image formation layer in the invention preferably contains a light-to-heat conversion material described below in order to obtain high sensitivity.

It is preferred in the invention that the hydrophilic layer contains the light-to-heat conversion material.

Materials having black color in the visible regions or materials, which are electro-conductive or semi-conductive, can be used.

Examples of the former include black iron oxide and black complex metal oxides containing at least two metals.

Examples of the latter include Sb-doped SnO₂ (ATO), Sn— added In₂O₃ (ITO), TiO₂, TiO prepared by reducing TiO₂ (titanium oxide nitride, generally titanium black). Particles prepared by covering a core material such as BaSO₄, TiO₂, 9Al₂O₃.2B₂O and K₂O.nTiO₂ with these metal oxides is usable. These oxides are particles having a particle diameter of not more than 0.5 μm, preferably not more than 100 nm, and more preferably not more than 50 nm.

As these light-to-heat conversion materials, black iron oxide or black complex metal oxides containing at least two metals are more preferred.

Examples of the black complex metal oxides include complex metal oxides comprising at least two selected from Al, Ti, Cr, Mn, Fe, Co, Ni, Cu, Zn, Sb, and Ba. These can be prepared according to the methods disclosed in Japanese Patent O.P.I. Publication Nos. 9-27393, 9-25126, 9-237570, 9-241529 and 10-231441.

The complex metal oxide used in the invention is preferably a complex Cu—Cr—Mn type metal oxide or a Cu—Fe—Mn type metal oxide. The Cu—Cr—Mn type metal oxides are preferably subjected to the treatment disclosed in Japanese Patent O.P.I. Publication Nos. 8-27393 in order to reduce isolation of a 6-valent chromium ion. These complex metal oxides have a high color density and a high light heat conversion efficiency as compared with another metal oxide.

The primary average particle diameter of these complex metal oxides is preferably from 0.001 to 1.0 μm, and more preferably from 0.01 to 0.5 μm. The primary average particle diameter of from 0.001 to 1.0 μm improves a light heat conversion efficiency relative to the addition amount of the particles, and the primary average particle diameter of from 0.05 to 0.5 μm further improves a light heat conversion efficiency relative to the addition amount of the particles. The light heat conversion efficiency relative to the addition amount of the particles depends on a dispersity of the particles, and the well-dispersed particles have a high light heat conversion efficiency. Accordingly, these complex metal oxide particles are preferably dispersed according to a known dispersing method, separately to a dispersion liquid (paste), before being added to a coating liquid for the particle containing layer. The metal oxides having a primary average particle diameter of less than 0.001 are not preferred since they are difficult to disperse. A dispersant is optionally used for dispersion. The addition amount of the dispersant is preferably from 0.01 to 5% by weight, and more preferably from 0.1 to 2% by weight, based on the weight of the complex metal oxide particles.

The content of the complex metal oxide in the hydrophilic layer is preferably from 20% by weight to less than 40% by weight, more preferably from 25% by weight to less than 39% by weight, and still more preferably from 25% by weight to less than 30% by weight, based on the total solid amount of hydrophilic layer. The content less than 20% by weight of the oxide provides poor sensitivity, while the content not less than 40% by weight of the oxide produces ablation scum due to ablation.

The hydrophilic layer or image formation layer in the invention can contain the following infrared absorbing dye as a light-to-heat conversion material.

Examples of the infrared absorbing dye include a general infrared absorbing dye such as a cyanine dye, a chloconium dye, a polymethine dye, an azulenium dye, a squalenium dye, a thiopyrylium dye, a naphthoquinone dye or an anthraquinone dye, and an organometallic complex such as a phthalocyanine compound, a naphthalocyanine compound, an azo compound, a thioamide compound, a dithiol compound or an indoaniline compound. Exemplarily, the light-to-heat conversion materials include compounds disclosed in Japanese Patent O.P.I. Publication Nos. 63-139191, 64-33547, 1-160683, 1-280750, 1-293342, 2-2074, 3-26593, 3-30991, 3-34891, 3-36093, 3-36094, 3-36095, 3-42281, 3-97589 and 3-103476. These compounds may be used singly or in combination.

The content of the infrared absorbing dye in the image formation layer is preferably from 0.1% by weight to less than 10% by weight, more preferably from 0.3% by weight to less than 7% by weight, and still more preferably from 0.5% by weight to less than 6% by weight, based on the total solid amount of hydrophilic layer. As is described above, the content less than 0.1% by weight of the oxide provides poor sensitivity, while the content not less than 10% by weight of the oxide produces ablation scum due to ablation.

Next, preparation of a planographic printing plate material of the invention will be explained.

The planographic printing plate material of the invention can be prepared by coating the subbing layer, image formation layer and hydrophilic layer in that order on the support described above employing a known coating method and drying the coated layer. Examples of the coating method include an extrusion coating method, a curtain coating method, a wire bar coating method, a gravure coating method, and a slide coating method.

### EXAMPLES

The present invention will be detailed employing the following examples, but the invention is not limited thereto. Preparation of Plastic Film Sheet Support

(1) Preparation of Polyester Film Sheet

(Polyethylene Terephthalate Film Sheet: PET Film Sheet)

Employing terephthalic acid and ethylene glycol, polyethylene terephthalate having an intrinsic viscosity of 0.66 (at 25° C. in a phenol/tetrachloroethane (6/4 by weight) solvent) was prepared according to a conventional method. The resulting polyethylene terephthalate was formed into pellets, dried at 130° C. for 4 hours, and melted at 300° C. The melted polyethylene terephthalate was extruded from a T-shaped die onto an electro-statically drum, and heat-fixed to obtain an unstretched sheet having an average thickness of 175 μm. The resulting sheet was stretched at 110° C. in the mechanical direction by a stretching magnification of 3.3, employing rolls having different circumferential velocity, and then stretched at 130° C. in the transverse direction by a stretching magnification of 4.5 in a tenter. Successively, The resulting stretched sheet was heat-fixed at 240° C. for 20 seconds and relaxed at 240° C. in the transverse direction by 4%. Thereafter, the sheet at the chuck portions in the tenter was cut off, and the both edges in the transverse direction of the sheet were subjected to knurling treatment to form knurls with a height of 10 μm and a width of 1 cm. Thus, a PET film sheet with a width of 2.5 m was prepared.

(2) Formation of Subbing Layer

The both surfaces of the sheet prepared above were subjected to corona discharge treatment at 8 W/m²·minute. Subsequently, the following subbing layer coating solution “a-1” was coated on one side of the sheet and dried to give a subbing layer A-1 with a dry thickness of 0.8 μm, and the following antistatic subbing layer coating solution “b-1” was coated on the surface of the sheet opposite the subbing layer A-1 and dried to give an antistatic subbing layer B-1 with a dry thickness of 0.8 μm and with an electric resistance of 10⁶ Ω. Subsequently, the subbing layer surfaces A and B were subjected to plasma treatment under conditions described later. Thus, a plastic film sheet support was obtained.

<<Subbing Layer Coating Solution “a-1”>>

| | |
|---|---|
| Latex of butyl acrylate/t-butyl acrylate/styrene/2- | 270 g |
| hydroxyethyl acrylate (30/20/25/25% by weight) | |
| Copolymer (Solid content of 30%) | |
| Hexamethylene-1,6-bis(ethyleneurea) | 0.8 g |
| Polyethylene particles (with an average | 0.05 g |
| particle diameter of 3 μm) | |
| Colloidal Silica | 0.1 g |
| (with an average particle diameter of 90 μm) | |

Water was added to make a 1 liter solution.

<<Subbing Layer Coating Solution “b-1”>>

| | |
|---|---|
| Tin oxide particles (with an average particle | 0.26 g/m² |
| diameter of 36 nm, doped with indium in an amount of 1%) | |
| Amount providing | |
| Latex of butyl acrylate/styrene/glycidyl acrylate (30/20/40 | 270 g |
| % by weight) copolymer (Solid content of 30%) | |
| Hexamethylene-1,6-bis(ethyleneurea) | 0.8 g |

Water was added to make a 1 liter solution. <<Plasma Treatment>>

The resulting subbed support was subjected to plasma treatment in the presence of a mixed gas of argon/nitrogen/hydrogen (90/5% by volume) at a high frequency output power of 4.5 kW and at a frequency of 5 kHz for 5 seconds, employing a batch type atmospheric pressure plasma treatment apparatus AP-I-H340 (produced by Iishii Kagaku Co., Ltd.).

Preparation of Under Layer Coating Solution

TABLE 1

| Materials | Amount |
|---|---|
| Colloidal silica (alkali type): Snowtex XS (solid | 54.38 g |
| 20% by weight, produced by Nissan Kagaku Co., | |
| Ltd.) | |
| Porous metal oxide particles Silton JC 40 (porous | 1.89 g |
| aluminosilicate particles having an average | |
| particle diameter of 4 μm, produced by Mizusawa | |
| Kagaku Co., Ltd.) | |
| Surface-coated melamine resin particles STM-6500S | 3.0 g |
| (average particle diameter of 6.5 μm, produced by | |
| Nissan Kagaku Co., Ltd.) | |
| Layer structural clay mineral particles: | 3.76 g |
| Montmorillonite Mineral Colloid MO gel prepared by | |
| vigorously stirring montmorillonite Mineral | |
| Colloid MO; gel produced by Southern Clay Products | |
| Co., Ltd. (average particle diameter: 0.1 μm) in | |
| water in a homogenizer to give a solid content of | |
| 5% by weight | |
| Cu—Fe—Mn type metal oxide black pigment: TM-3550 | 10 g |
| black aqueous dispersion {prepared by dispersing | |
| TM-3550 black powder having a particle diameter of | |
| 0.1 μm produced by Dainichi Seika Kogyo Co., Ltd. | |
| in water to give a solid content of 40.5% by | |
| weight (including 0.5% by weight of dispersant)} | |
| Aqueous 10% by weight sodium | 0.48 g |
| phosphate.dodecahydrate solution (Reagent produced | |
| by Kanto Kagaku Co., Ltd.) | |
| Pure water | 26.49 g |
| Solid content (% by weight) | 20% |

Materials as shown in Table 1 were mixed with vigorous stirring in a homogenizer, and filtered to obtain an under layer coating solution (with a solid content of 20% by weight).

Preparation of Hydrophilic Layer Coating Solution

TABLE 2

| Material | Amount |
|---|---|
| Colloidal silica (alkali type): Snowtex S (solid | 10.4 g |
| 30% by weight, produced by Nissan Kagaku Co., | |
| Ltd.) | |
| Necklace shaped colloidal silica (alkali type): | 23.4 g |
| Snowtex PSM (solid 20% by weight, produced by | |
| Nissan Kagaku Co., Ltd.) | |
| Porous metal oxide particles Silton JC 20 | 1.2 g |
| (porous aluminosilicate particles having an | |
| average particle diameter of 2 μm, produced by | |
| Mizusawa Kagaku Co., Ltd.) | |
| Porous metal oxide particles Silton AMT 08 | 1.5 g |
| (porous aluminosilicate particles having an | |
| average particle diameter of 0.6 μm, produced by | |
| Mizusawa Kagaku Co., Ltd.) | |
| Layer structural clay mineral particles: | 4.8 g |
| Montmorillonite Mineral Colloid MO gel prepared | |
| by vigorously stirring montmorillonite Mineral | |
| Colloid MO; gel produced by Southern Clay | |
| Products Co., Ltd. (average particle diameter: | |
| 0.1 μm) in water in a homogenizer to give a | |
| solid content of 5% by weight | |
| Cu—Fe—Mn type metal oxide black pigment: TM-3550 | 2.7 g |
| black aqueous dispersion {prepared by dispersing | |
| TM-3550 black powder having a particle diameter | |
| of 0.1 μm produced by Dainichi Seika Kogyo Co., | |
| Ltd. in water to give a solid content of 40% by | |
| weight (including 0.2% by weight of dispersant)} | |
| Aqueous 4% by weight sodium carboxymethyl | 3.0 g |
| cellulose solution (Reagent produced by Kanto | |
| Kagaku Co., Ltd.) | |
| Aqueous 10% by weight sodium | 0.6 g |
| phosphate.dodecahydrate solution (Reagent | |
| produced by Kanto Kagaku Co., Ltd.) | |
| Pure water | 52.4 g |
| Solid content (% by weight) | 12% |

Materials as shown in Table 2 were mixed with vigorous stirring in a homogenizer, and filtered to obtain a hydrophilic layer coating solution (with a solid content of 12% by weight).

Formation of Hydrophilic Layer and Second Hydrophilic Layer

The second hydrophilic layer coating solution was coated on the subbing layer A-1 side of the support obtained above employing a wire bar #3, and allowed to pass through a 100° C. drying zone with a length 15 m at a transportation speed of 15 m/minute to obtain a second hydrophilic layer with a coating amount of 3.0 g/m². Successively, the hydrophilic layer coating solution was coated on the resulting second hydrophilic layer employing a wire bar #4, and allowed to pass through a 100° C. drying zone with a length 30 m at a transportation speed of 15 m/minute to obtain a second hydrophilic layer with a coating amount of 0.55 g/m². The resulting material was further subjected to aging treatment at 60° C. for one day.

Formation of Image Formation Layer

The image formation layer coating solution having the composition as shown in Table 3 was coated on the resulting second hydrophilic layer above employing a wire bar #5, and allowed to pass through a 60° C. drying zone with a length 30 m at a transportation speed of 15 m/minute to obtain an image formation layer with a coating amount of 0.5 g/m². The resulting material was further subjected to aging treatment at 40° C. for three days. Thus, printing plate material sample 001 through 009 were prepared.

TABLE 3

| Image | | | | | | | | | | | | |
|---|---|---|---|---|---|---|---|---|---|---|---|---|
| Formation | | | | | | | | | | | | |
| Layer | | | | | | | | | | | | |
| Coating | Materials and Addition Amount | | | | | | | | | | Solid | |
| Solution | | | | | | | | | | Pure | Content | |
| No. | A | B | C | D | E | F | G | H | I | Water | (weight %) | Remarks |
| 1 | 11.03 g | 12.60 g | 2.10 g | | | | | | | 74.28 g | 6.30 | Comp. |
| 2 | 10.95 g | 12.60 g | 2.10 g | 0.03 g | | | | | | 74.32 g | 6.30 | Inv. |
| 3 | 10.24 g | 12.60 g | 2.10 g | 0.32 g | | | | | | 74.75 g | 6.30 | Inv. |
| 4 | 6.30 g | 12.60 g | 2.10 g | 1.89 g | | | | | | 77.11 g | 6.30 | Inv. |
| 5 | 10.24 g | 12.60 g | 2.10 g | | 0.32 g | | | | | 74.75 g | 6.30 | Inv. |
| 6 | 10.24 g | 12.60 g | 2.10 g | | | 0.32 g | | | | 74.75 g | 6.30 | Inv. |
| 7 | 10.24 g | 12.60 g | 2.10 g | | | | 0.32 g | | | 74.75 g | 6.30 | Inv. |
| 8 | 10.24 g | 12.60 g | 2.10 g | | | | | 0.32 g | | 74.75 g | 6.30 | Inv. |
| 9 | 10.24 g | 12.60 g | 2.10 g | | | | | | 0.32 g | 74.75 g | 6.30 | Inv. |

Comp: Comparative,
Inv.: Inventive

Materials A through I in Table 1 are as follows:
A: Carnauba wax emulsion A118 (with an average particle diameter of 0.3 μm, a softening point of 65° C., a melting point of 80° C., a melt viscosity at 140° C. of 8 cps and a solid content of 40% by weight, produced by Gifu Shellac Co., Ltd.)
B: Aqueous solution of disaccharide trehalose powder Treha (mp. 97° C., produced by Hayashihara Shoji Co., Ltd.) having a solid content of 10% by weight
C: Sodium acrylate DL-522 (with an average molecular weight of 170,000 and a solid content of 30% by weight, produced by Nippon Shhokubai Co., Ltd.)
D: Calcium carbonate Luminus with an average particle diameter of 0.1 μm and a refractive index of 1.58 (produced by Maruo Karusiumu Co., Ltd.)
E: Calcium carbonate N-2 with an average particle diameter of 0.04 μm and a refractive index of 1.58 (produced by Maruo Karusiumu Co., Ltd.)
F: Calcium carbonate Calseeds X-25 with an average particle diameter of 0.25 μm and a refractive index of 1.58 (produced by Kamishima Kagaku Co., Ltd.)
G: Calcium carbonate Super #2300 with an average particle diameter of 2.3 μm and a refractive index of 1.58 (produced by Maruo Karusiumu Co., Ltd.)
H: Barium sulfate B-54 with an average particle diameter of 1.2 μm and a refractive index of 1.64 (produced by Sakai Kagaku Co., Ltd.)
I: Barium sulfate B-55 with an average particle diameter of 0.55 μm and a refractive index of 1.64 (produced by Sakai Kagaku Co., Ltd.)

Printing plate material samples 001 through 009 were exposed according to the following method to obtain printing plate samples 101 through 109, respectively. In the resulting printing plate samples 101 through 109, reflection density at exposed portions and unexposed portions were measured, and visualization due to exposure was visually evaluated. The results are shown in Table 4.

TABLE 4

| Printing | | Image | Reflection | Reflection | | | |
|---|---|---|---|---|---|---|---|
| Plate | Printing | Formation | Density at | Density at | | | |
| Material | Plate | Layer | Exposed | Unexposed | | Visualization | |
| Sample | Sample | Coating | Portions | Portions | ΔD | due to | |
| No. | No. | Solution | (Dex) | (Dunex) | (Dex - Dunex) | Exposure | Remarks |
| 001 | 101 | 1 | 2.5 | 2 | 0.5 | 2 | Comp. |
| 002 | 102 | 2 | 2.5 | 1.8 | 0.7 | 4 | Inv. |
| 003 | 103 | 3 | 2.5 | 1.7 | 0.8 | 5 | Inv. |
| 004 | 104 | 4 | 2.4 | 1.7 | 0.7 | 4 | Inv. |
| 005 | 105 | 5 | 2.5 | 1.9 | 0.6 | 3 | Inv. |
| 006 | 106 | 6 | 2.5 | 1.7 | 0.8 | 5 | Inv. |
| 007 | 107 | 7 | 2.4 | 1.8 | 0.6 | 4 | Inv. |
| 008 | 108 | 8 | 2.5 | 1.7 | 0.8 | 5 | Inv. |
| 009 | 109 | 9 | 2.5 | 1.7 | 0.8 | 5 | Inv. |

Comp.: Comparative,
Inv: Inventive

Exposure (Image Formation)

The printing plate material obtained above was wound around the exposure drum of an exposure device, fixed thereon, and exposed. Employing 830 laser beams with a wavelength of 830 nm and a spot diameter of 18 μm, exposure was carried out at exposure energy of 200 mJ/cm² to form an image at 2400 dpi and at a screen line number of 175.

Exposure and Image Formation

Measurement of Reflection Density

Reflection density was measured employing X-rite 530 produced by X-rite Co., Ltd.

Visualization Due to Exposure

Visualization due to exposure was evaluated according to the following criteria. In the evaluation, Ranking 3 or more is practically preferred.
Ranking 5: Chinese characters “ [symbol] ”, which was written in the form of Mincho at point 3, were clearly visible.
Ranking 4: Chinese characters “ [symbol] ”, which was written in the form of Mincho at point 5, were clearly visible.
Ranking 3: Chinese characters “ [symbol] ”, which was written in the form of Mincho at point 7, were clearly visible.
Ranking 2: Chinese characters “ [symbol] ”, which was written in the form of Mincho at point 12, were clearly visible.
Ranking 1: No contrast was produced between the exposed portions and unexposed portions.
   (Printing Method)

Printing was carried out employing a printing press, DAIYA 1F-1 produced by Mitsubishi Jukogyo Co., Ltd. and employing a coated paper, a 2% by weight solution of Astromark 3 (produced by Nikken Kagaku Kenkyusyo Co., Ltd.), and printing ink (Toyo King Hyecho M Magenta, produced by Toyo Ink Manufacturing Co.).

Evaluation of Initial Printability

The number of paper sheets printed from when printing started till when an image with a good S/N ratio (where no stain was observed at non-image portions, i.e., in the image formation layer the non-image portions were completely removed on a press, and the image portions had a sufficient density) was obtained was counted as the number of paper wastes and evaluated as a measure of initial printability. The less the number of paper wastes is, the better the initial printability. The number of paper wastes of not less than 40 is practically problematic. Evaluation of Printing Durability

The number of paper sheets printed from when printing started till when elimination of dots at the 3% dot image portion or density reduction at solid image potions was observed was counted and evaluated as printing durability. The more the number, the higher printing durability is.

The results are shown in Table 5.

TABLE 5

| Printing Plate | Initial | Printing | |
|---|---|---|---|
| Sample No. | Printability | Durability | Remarks |
| 101 | 20 | 20,000 | Comparative |
| 102 | 20 | 20,000 | Inventive |
| 103 | 20 | 20,000 | Inventive |
| 104 | 20 | 20,000 | Inventive |
| 105 | 20 | 20,000 | Inventive |
| 106 | 20 | 20,000 | Inventive |
| 107 | 20 | 20,000 | Inventive |
| 108 | 20 | 20,000 | Inventive |
| 109 | 20 | 20,000 | Inventive |

As apparent from Tables 4 and 5, the present invention improves visualization due to exposure without lowering printing properties.

### EFFECT OF THE INVENTION

The planographic printing plate material of the invention, comprising an image formation layer containing extender pigment, can provide excellent visualization due to exposure

1. A planographic printing plate material comprising a plastic film sheet support and provided thereon, a hydrophilic layer and an image formation layer in that order, wherein the image formation layer contains extender pigment.

2. The planographic printing plate material of claim 1, wherein the extender pigment is in the form of particles and the particles have an average particle diameter of from 0.05 μm to less than 2 μm.

3. The planographic printing plate material of claim 1, wherein the extender pigment content of the image formation layer is from 1% by weight to less than 25% by weight.

4. The planographic printing plate material of claim 1, wherein the extender pigment has a refractive index of from 1.35 to less than 1.7.

5. The planographic printing plate material of claim 1, wherein the extender pigment is one selected from the group consisting of calcium carbonate, barium sulfate and titanium oxide.

6. The planographic printing plate material of claim 1, wherein the image formation layer further contains heat-melting particles or heat-fusible particles.

7. The planographic printing plate material of claim 1, wherein the hydrophilic layer consists of two hydrophilic layers, which are formed according to a coating method.

8. The planographic printing plate material of claim 1, wherein the hydrophilic layer contains metal oxide particles with an average particle diameter of from 3 to 100 nm.

9. The planographic printing plate material of claim 8, wherein the metal oxide particles are colloidal silica.

10. The planographic printing plate material of claim 8, wherein the hydrophilic layer further contains a light-to-heat conversion material.

11. The planographic printing plate material of claim 1, wherein the plastic film sheet support is that of polyethylene terephthalate or polyethylene naphthalate.

12. A printing process comprising the step of writing an image based on image information on the planographic printing plate material of any one of claims 1 through 11, employing infrared laser, and carrying out printing, employing the resulting planographic printing plate material wihtout being subjected to special development.
